(19) United States
(12) Patent Application Publication
(10) Pub. No.: US 2025/0342882 A1
(43) Pub. Date: Nov. 6, 2025

(54) VOLTAGE CONTROL CIRCUITS AND METHODS FOR OPERATING THE SAME

(71) Applicant: Taiwan Semiconductor Manufacturing Company, Ltd., Hsinchu (TW)

(72) Inventors: Zheng-Jun Lin, Hsinchu City (TW); Che-Min Hung, Hsinchu City (TW); Chung-Cheng Chou, Hsinchu City (TW)

(73) Assignee: Taiwan Semiconductor Manufacturing Company, Ltd., Hsinchu (TW)

(21) Appl. No.: 18/652,963

(22) Filed: May 2, 2024

(51) Int. Cl. G05F 1/56; G11C 13/00

(52) U.S. Cl. CPC G05F 1/56; G11C 13/0038

(57) ABSTRACT

A voltage control circuit includes an amplifier having a first terminal and a second terminal; a first current source having a control terminal connected to an output terminal of the amplifier and configured to provide a first current; a plurality of second current sources each having a control terminal connected to the output terminal of the amplifier and each configured to provide a second current; and a plurality of switches, each of the plurality of switches having a first terminal selectively connected to a first terminal of a corresponding one of the second current sources. One or more of the plurality of switches are configured to be activated to conduct one or more of the corresponding second currents, causing the circuit to provide a plurality of adjustable voltages.

### BACKGROUND

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node (e.g., shrinking the process node towards the sub-10 nm node). Commensurate with shrunken dimensions is an expectation of greater immediacy (higher speed) and increased performance with reduced power consumption.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example block diagram of a memory circuit including a voltage control circuit, in accordance with some embodiments.

FIG. 2 illustrates an example circuit diagram of the voltage control circuit of FIG. 1, in accordance with some embodiments.

FIG. 3 illustrates an example schematic diagram of the voltage control circuit of FIG. 2 coupled to a plural number of memory arrays, in accordance with some embodiments.

FIG. 4 illustrates an example schematic diagram of the voltage control circuit of FIG. 2 coupled to a memory array, in accordance with some embodiments.

FIG. 5 illustrates an example schematic diagram of a plural number of local LDO regulators controlled by a respective set of switches, in accordance with some embodiments.

FIG. 6 illustrates an example schematic diagram of a current detector coupled to the voltage control circuit of FIG. 2, in accordance with some embodiments.

FIG. 7 illustrates a flow chart of an example method for operating a voltage control circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A low-dropout (LDO) regulator is a voltage regulator characterized by a small difference between input voltage and output voltage. LDO regulators have many and various uses in integrated circuit (IC) applications. For example, a memory circuit typically includes a plural number of LDO regulators, each of which is configured to provide a respective voltage to operate the memory circuit. In the existing technologies, these plural LDO regulators typically share a common current source. To accommodate various voltages operating the memory circuit, the common current source is typically characterized with the capability to supply a substantially large current. However, with such a large current, unnecessary power consumption (e.g., a large standby current) is induced, which disadvantageously impact overall performance of the corresponding circuit. Accordingly, the existing integrated circuits with a LDO regulator have not been entirely satisfactory in certain aspects.

The present disclosure provides various embodiments of a memory circuit including a plural number of current sources that can each be controlled (e.g., activated) by a respective switch. The memory circuit may include a plural number of memory cells formed as one or more memory arrays, each of the memory cells configured to store at least one data bit. In one aspect, the memory circuit can include a plural number of local LDO regulators driven by the different current sources, respectively. Each of the local LDO regulators can provide a respective voltage to operate one or more of the memory cells. In another aspect, the memory cells may be configured in a plural number of operations modes (e.g., operation voltages). The different operation voltages can be provided by the current sources, respectively. In yet another aspect, the memory circuit may include different densities of memory cells (e.g., formed as respective memory arrays), which may be operated under respective operations voltages. Such different operations voltage can be provided by the current sources, respectively. With such configurable current sources, the memory circuit, as disclosed herein, can optimize its power usage. As a non-limiting example, when the memory circuit is in a low-power mode, a fewer number of current sources can be activated, which can advantageously reduce unnecessary standby current being constantly provided.

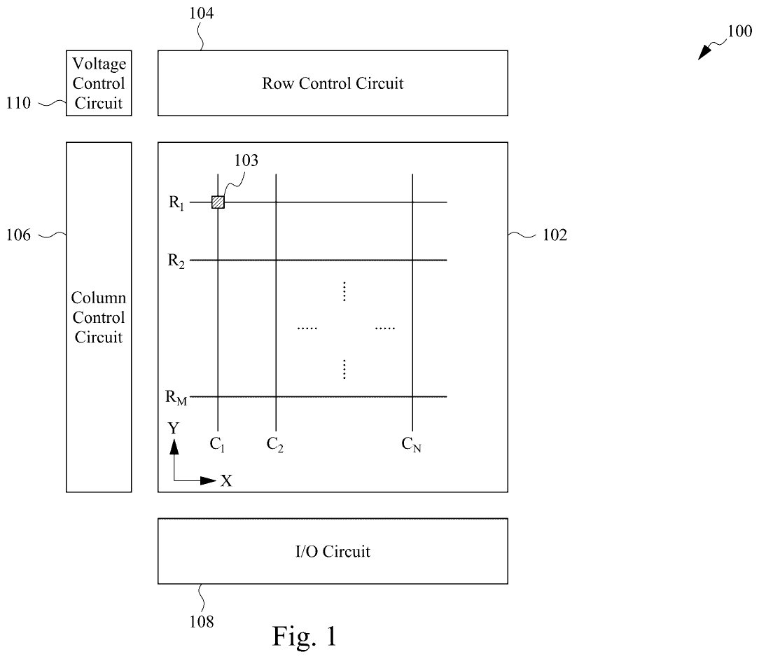

FIG. 1 illustrates a block diagram of an example circuit 100 including a voltage control circuit that can be configured to provide different voltages for operating a memory array, in accordance with various embodiments. For example, the memory circuit 100 can include a memory array 102, a row control circuit (e.g., a driver and/or decoder) 104, a column control circuit (e.g., a driver and/or decoder) 106, an input/output (I/O) circuit 108, and a voltage control circuit 110. Despite not being expressly shown in FIG. 1, all of the components of the memory circuit 100 may be operatively coupled to one another. Although, in the illustrated embodiment of FIG. 1, each component is shown as a separate block for the purpose of clear illustration, in some other embodiments, some or all of the components shown in FIG. 1 may be integrated together.

The memory array 102 is a hardware component that stores data. In various embodiments, the memory array 102 is embodied as a semiconductor memory device. The memory array 102 includes a plurality of memory cells (or otherwise storage units) 103. The memory array 102 includes a number of rows R₁, R₂, R₃ . . . R_{M}, each extending in a first direction (e.g., the X-direction) and a number of columns C₁, C₂, C₃ . . . C_{N}, each extending in a second direction (e.g., the Y-direction). Each of the rows and columns may include one or more conductive (e.g., metal) structures functioning as access lines, e.g., bit lines (BLs), word lines (WLs), and source/select lines (SLs). Each memory cell 103 is arranged in the intersection of a corresponding row and a corresponding column, and can be operated according to voltages or currents through the respective conductive structures of the column and row. For example, each of the rows may include one or more corresponding WLs, and each of the columns may include one or more corresponding BLs and one or more corresponding SLs.

In some embodiments, each memory cell 103 is embodied as a Resistive Random Access Memory (RRAM) cell. However, it should be understood that the memory cell 103 can be implemented as any of various other non-volatile memory cells, while remaining within the scope of the present disclosure. For example, memory cell 103 may include a magnetoresistive random access memory (MRAM) cell, a phase-change random access memory (PCRAM) cell, an efuse memory cell, an anti-fuse memory cell, etc.

In the example of being implemented as an RRAM cell, the memory cell 103 may include a resistor and a transistor coupled to each other in series. The memory cell 103 can be operatively coupled a corresponding set of BL, WL, and SL. The resistor may be formed as a multi-layer stack that includes a top electrode (TE), a capping layer, a variable resistance dielectric (VRD) layer, and a bottom electrode. In some embodiments, the VRD layer may be formed from at least one of the transition metal oxide materials such as, TiOx, NiOx, HfOx, NbOx, CoOx, FeOx, CuOx, VOx, TaOx, WOx, CrOx, and combinations thereof. In some embodiments, the VRD layer may include a high-k dielectric layer. The VRD layer can switch between a high resistance state (HRS) and a low resistance state (LRS), which can correspond to logic 0 and logic 1 of the data bit stored (or programmed) in the memory cell 103.

In general, the TE of the resistor can be coupled to the corresponding BL, the BE of the resistor can be coupled to a first source/drain terminal of the transistor, a gate terminal of the transistor is coupled to the corresponding WL, and a second source/drain terminal of the transistors is coupled to the corresponding SL. To operate the memory cell 103 (which is implemented as an RRAM cell), the transistor is activated (i.e., turned on) by an assertion signal through the WL, and then a voltage with a polarity (e.g., BL is provided with a positive voltage and SL is ground) is applied across the memory cell 103. As such, the higher voltage at BL (and TE) pulls negatively charged oxygen ions from the VRD layer to the capping layer and thus leaves oxygen vacancies within the VRD layer, which allows electron(s) that are present in the BE to travel (hop) from the BE through the VRD and capping layers, and ultimately to the TE. Consequently, a conduction path through the VRD layer is “formed.” Before such a conduction path is formed, the resistor may remain at the HRS. In some embodiments, upon formation of the conduction path, the resistor transitions from the HRS to the LRS, and a relatively higher magnitude of current flows between the BL and the SL.

The row control circuit 104 is a hardware component that can receive a row address of the memory array 102 and assert one or more conductive structures (e.g., a WL) at that row address. The column control circuit 106 is a hardware component that can receive a column address of the memory array 102 and assert one or more conductive structures (e.g., a BL and a SL) at that column address. The I/O circuit 108 is a hardware component that can access (e.g., read, program) each of the memory cells 103 asserted through the row decoder 104 and column decoder 106.

In various embodiments of the present disclosure, the voltage control circuit 110 is a hardware component that can provide a number of suitable voltages to access or otherwise operate the memory array through the row control circuit 104, column control circuit 106, and I/O circuit 108, respectively. For example, the voltage control circuit 110 can include a global LDO regulator configured to provide a standby current, a plural number of charging current sources selectively activated through corresponding switches so as to provide respective levels of a charging current, and a number of local LDO regulators configured to provide respective operation voltages for the memory array 102 based on the different charging current levels.

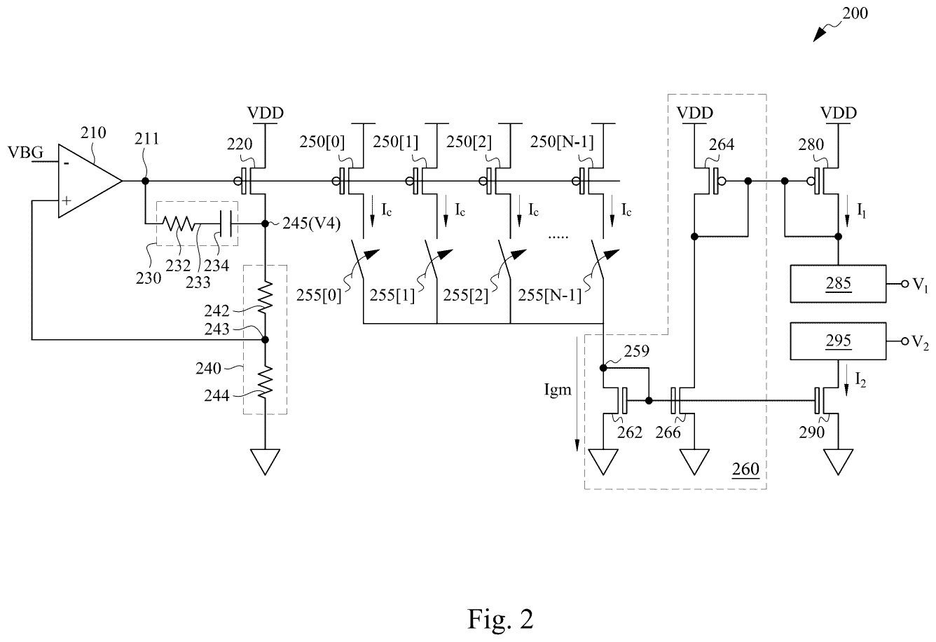

FIG. 2 illustrates an example circuit diagram 200 of the voltage control circuit 110 (herein after “voltage control circuit 200”), in accordance with various embodiments of the present disclosure. In general, the voltage control circuit 200 can include a plural number of charging current sources selectively activated, so as to provide a plural number of charging current levels for at least one memory array. However, it should be understood that, in some other embodiments, the voltage control circuit 200 is not limited to providing charging current levels for a memory array. Further, the circuit diagram of FIG. 2 has been simplified, and thus, the voltage control circuit 200 can include any of various other components while remaining within the scope of the present disclosure.

As shown, the voltage control circuit 200 includes an error amplifier 210, a standby current source 220, a mirror compensation circuit 230, a voltage divider 240, a plural number of charging current sources, 250[0], 250[1], 250[2]. . . 250[N−1], a plural number of switches, 255[0], 255[1], 255[2]. . . 255[N−1], a current mirror 260, and a number of LDO regulators, 285 and 295. Although four charging current sources (and four corresponding switches) are shown, it should be understood that the number “N” can be any integer number equal to or larger than 2.

In some embodiments, the error amplifier 210, the standby current source 220, the mirror compensation circuit 230, and the voltage divider 240 may collectively serve as a global LDO regulator, while each of the LDO regulators 285 and 295 may each serve as a local LDO regulator configured to provide an operation voltage (e.g., V₁, V₂) for a coupled memory array (not shown). In some embodiments, each of the local LDO regulators, e.g., 285 and 295, may be substantially to the global LDO regulator, and thus, the description will not be repeated. The operation voltage, e.g., V₁, V₂, can be determined based on a current level of a total charging current, I_{gm}, which will be discussed in further detail below.

An output voltage (Vₓ) present at an output node 245 of the global LDO regulator (210, 220, 230, and 240) can be regulated through a feedback loop including the voltage divider 240, the error amplifier 210, and the standby current source 220. The output voltage Vₓ is divided by the voltage divider 240. The voltage divider 240 is considered a feedback circuit having an input terminal electrically connected to an output terminal of the standby current source 220, and an output terminal electrically connected to a non-inverting input terminal of the error amplifier 210. Atop resistor 242 of the voltage divider 240 is electrically connected to the output node 245 of the global LDO regulator and a divider node 243. A bottom resistor 244 of the voltage divider 240 is electrically connected to the divider node 243 and a voltage supply node (e.g., ground). Division of the output voltage Vₓ by the voltage divider 240 causes divided voltage at the divider node 243 to be a fraction of the output voltage Vₓ. The fraction is controlled by a ratio of resistance of the bottom resistor 244 to total resistance of the bottom resistor 244 and the top resistor 242.

The mirror compensation circuit 230 is electrically connected to the gate node 211 and the output node 245. The mirror compensation circuit 230 includes a resistor 232 and a capacitor 234. A first terminal of the resistor 232 is electrically connected to the gate node 211. A second terminal of the resistor 232 is electrically connected to an internal node 233 of the mirror compensation circuit 230. A first terminal of the capacitor 234 is electrically connected to the internal node 233. A second terminal of the capacitor 234 is electrically connected to the output node 245.

A first input terminal (e.g., a positive input terminal, non-inverting input terminal) of the error amplifier 210 is electrically connected to the divider node 243, and receives the divided voltage from the voltage divider 240. A second input terminal (e.g., a negative input terminal, inverting input terminal) of the error amplifier 210 is electrically biased by a reference voltage VBG. In some embodiments, the reference voltage VBG is generated by a bias circuit, such as a bandgap voltage reference. An output terminal of the error amplifier 210 is electrically connected to a gate node 211. Error voltage at the output terminal of the error amplifier 210 is a product of gain of the error amplifier 210 and difference between the reference voltage VBG and the divided voltage.

The error voltage controls the standby current source 220 and the charging current sources 250[0] to 250[N−1]. In some embodiments, the standby current source 220 is a P-type metal-oxide-semiconductor (PMOS) transistor. A gate electrode of the standby current source 220 is electrically connected to the gate node 211. A source electrode of the standby current source 220 is electrically connected to another voltage supply node (e.g., VDD). A drain electrode of the standby current source 220 is electrically connected to the output node 245 of the global LDO regulator. In some embodiments, the standby current source 220 has a first width (W₁) and a first length (L₁). A standby ratio, equaling the first width divided by the first length (W₁/L₁), is directly proportional to transimpedance (current/voltage) gain of the standby current source 220. For example, a larger standby ratio (W₁/L₁) causes greater output current for a given input voltage.

In various embodiments, the charging current sources 250[0] to 250[N−1] may each be implemented as a PMOS transistor. However, it should be understood other implementation can be contemplated while remaining within the scope of the present disclosure. A gate electrode of each of the charging current sources 250[0] to 250[N−1] is electrically connected to the gate node 221. A source electrode of each of the charging current sources 250[0] to 250[N−1] is electrically connected to VDD, without other component coupled therebetween. A drain electrode of each of the charging current sources 250[0] to 250[N−1] can be selectively connected to an input node 259 of the current mirror 260 through a corresponding one of the switches 255[0] to 255[N−1]. For example, the drain electrode of the charging current source 250[0] is selectively connected to the node 259 through the switch 255[0]; the drain electrode of the charging current source 250[1] is selectively connected to the node 259 through the switch 255[1]; the drain electrode of the charging current source 250[2] is selectively connected to the node 259 through the switch 255[2]; and the drain electrode of the charging current source 250[N−1] is selectively connected to the node 259 through the switch 255[N−1]. Each of the switches 255[0] to 255[N−1] may be implemented as a pass gate, an NMOS transistor, a PMOS transistor, or the like.

Specifically, a first terminal of the switch 255 (one of the switches 255[0] to 255[N−1]) is electrically connected to the drain electrode of the corresponding charging current source (one of the charging current sources 250[0] to 250[N−1]). A second terminal of each of the switches 255[0] to 255[N−1] is electrically connected to the node 259. The switches 255[0] to 255[N−1] can be controlled (e.g., activated) by respective switching signals. The charging current sources 250[0] to 250[N−1] may each have a second width (W₂) and a second length (L₂). A charging ratio, equaling the second width divided by the second length (W₂/L₂), is directly proportional to transimpedance (current/voltage) gain of the charging current source. For example, a larger charging ratio (W₂/L₂) causes greater output current for a given input voltage. Further, the charging current sources 250[0] to 250[N−1] may have respectively different width to length ratios.

In various embodiments, each of the charging current sources 250[0] to 250[N−1] can provide a respective charging current (I_{c}), upon the corresponding switch being activated. As such, the total charging current, I_{gm}, can be a sum of the conducted charging currents. For example, if the switch 255[0] is activated while all other switches are deactivated, the total charging current, I_{gm}, is equal to 1×I_{c}. In another example, if the switch 255[0] and 255[1] are activated while all other switches are deactivated, the total charging current, I_{gm}, is equal to 2×L_{c}, or a sum of the charging currents flowing through the charging current sources 250[0] and 250[1]. Further, at least one of the switches 255[0] to 255[N−1] is configured to be activated, in various embodiments.

The total charging current, I_{gm}, can be mirrored or copied by the current mirror 260, which includes an NMOS transistor 262, a PMOS transistor 264, and another NMOS transistor 266. Such a mirrored current can be provided to the local LDO regulators 285 and 295 as I₁ and I₂ through transistors 280 and 290, respectively. The transistors 280 and 290 can serve as current sources for the local LDO regulators 285 and 295, respectively. It should be understood that a ratio of I_{gm} to I₁ and a ratio of I_{gm} to I₂ can each be adjusted to any desired value, according to various characteristics of the current mirror 260 (e.g., a W/L ratio of the transistor 264 versus a W/L ratio of the transistor 280, a W/L ratio of the transistor 266 versus a W/L ratio of the transistor 290, etc.). By providing the currents I₁ and I₂ with respective current levels, the operation voltages V₁ and V₂ can each be adjusted to any desired voltage level. In various embodiments, the operations voltages V₁ and V₂, outputted by the local LDO regulators 285 and 295, can be utilized for different functions of the coupled memory array. For example, the operation voltage V₁ can be applied on an asserted WL (through a row control circuit) for writing or reading a corresponding memory cell. In another example, the operation voltage V₂ can be applied on an asserted BL (through a column control circuit) for writing or reading a corresponding memory cell.

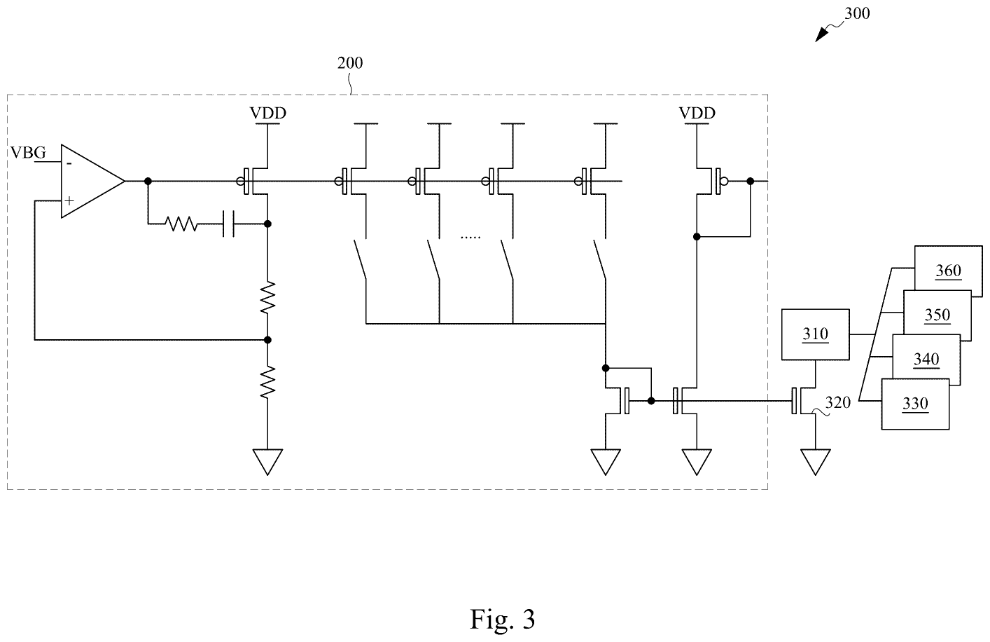

FIG. 3 illustrates an example schematic diagram 300 of the voltage control circuit 200 (FIG. 2) coupled to a plural number of memory arrays, e.g., 330, 340, 350, 360, etc., in accordance with various embodiments of the present disclosure. The voltage control circuit 200 can be coupled to the memory arrays 330 to 360 through at least one local LDO regulator 310 and transistor 320. The transistor 320 can function as a current source for the local LDO regulator 310. In some embodiments, the memory arrays 330 to 360 may have respectively different sizes (e.g., different numbers of memory cells), which may cause their respective operation voltages to be different. For a bigger memory array, the voltage control circuit 200 can provide a higher operation voltage, by increasing the current level of the total charging current, I_{gm}. Accordingly, the voltage control circuit 200 can activate more switches to allow more charging current sources to contribute their charging currents to the total charging current, I_{gm}. For a smaller memory array, the voltage control circuit 200 can provide a lower operation voltage, by decreasing the current level of the total charging current, I_{gm}. Accordingly, the voltage control circuit 200 can activate fewer switches to allow fewer charging current sources to contribute their charging currents to the total charging current, I_{gm}.

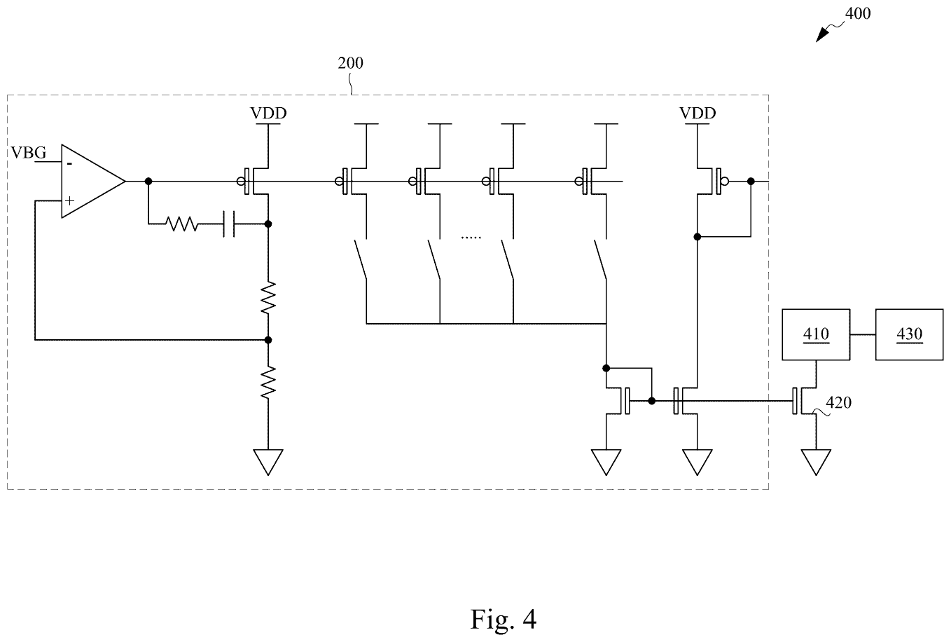

FIG. 4 illustrates an example schematic diagram 400 of the voltage control circuit 200 (FIG. 2) coupled to a memory array 430, in accordance with various embodiments of the present disclosure. The voltage control circuit 200 can be coupled to the memory array 430 through at least one local LDO regulator 410 and transistor 420. The transistor 420 can function as a current source for the local LDO regulator 410. In some embodiments, the memory array 430 may have a plural number of operation modes, which may cause their respective operation voltages to be different. For example, the memory array 430 may be configured with at least a low-power mode and a high-performance mode. When the memory array 430 is configured at the high-performance mode, the voltage control circuit 200 can provide a higher operation voltage, by increasing the current level of the total charging current, I_{gm}. Accordingly, the voltage control circuit 200 can activate more switches to allow more charging current sources to contribute their charging currents to the total charging current, I_{gm}. When the memory array 430 is configured at the low-power mode, the voltage control circuit 200 can provide a lower operation voltage, by decreasing the current level of the total charging current, I_{gm}. Accordingly, the voltage control circuit 200 can activate fewer switches to allow fewer charging current sources to contribute their charging currents to the total charging current, I_{gm}.

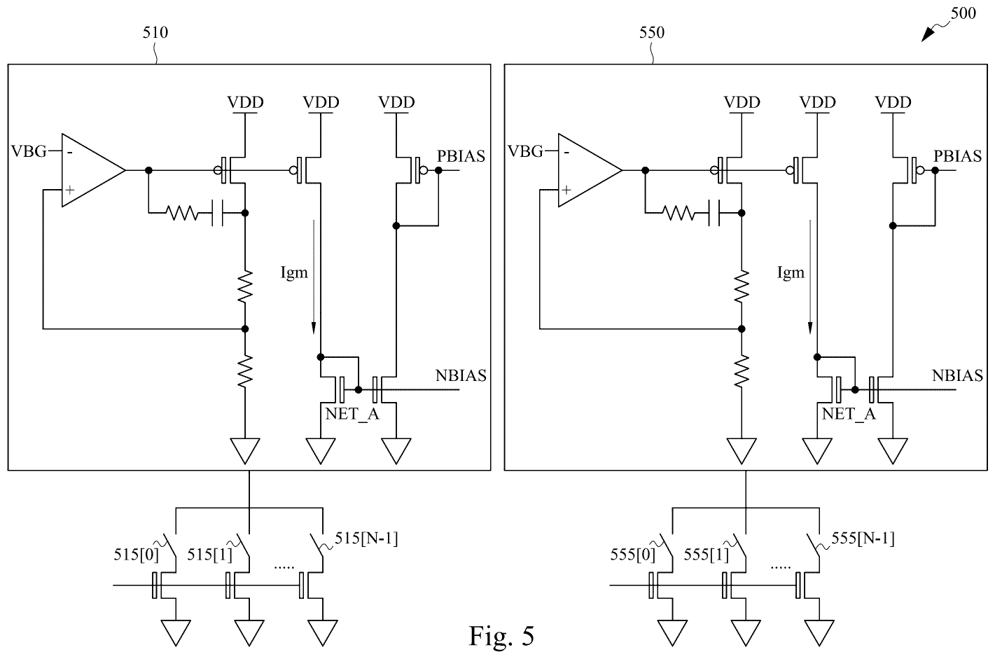

FIG. 5 illustrates an example schematic diagram 500 including multiple local LDO regulators, e.g., 510 and 550, that are controlled by respective sets of switches, e.g., 515 and 555, to drive different loading of circuits, in accordance with various embodiments of the present disclosure. As shown, LDO regulator 510 and LDO regulator 550 are coupled to a first set of switches 515 (e.g., 515[0], 515[1] . . . 515[N−1]) and a second set of switches 555 (e.g., 555[0], 555[1]. . . 555[N−1]), respectively. In some embodiments, the LDO regulators 510 and 550 are each substantially similar to the voltage control circuit 200 (FIG. 2) described above, except that the LDO regulator 510 or 550 may not include switches to adjust an output voltage. Instead, the output voltage of the LDO regulators 510 and 550 may be adjusted by the respective sets of switches, 515 and 555. For example, the LDO regulator 510 can be coupled to a circuit that is configured to operate with a higher voltage, and the LDO regulator 550 can be coupled to a circuit that is configured to operate with a lower voltage. Accordingly, a greater number of switches 515 can be activated, while a fewer number of switches 555 can be activated.

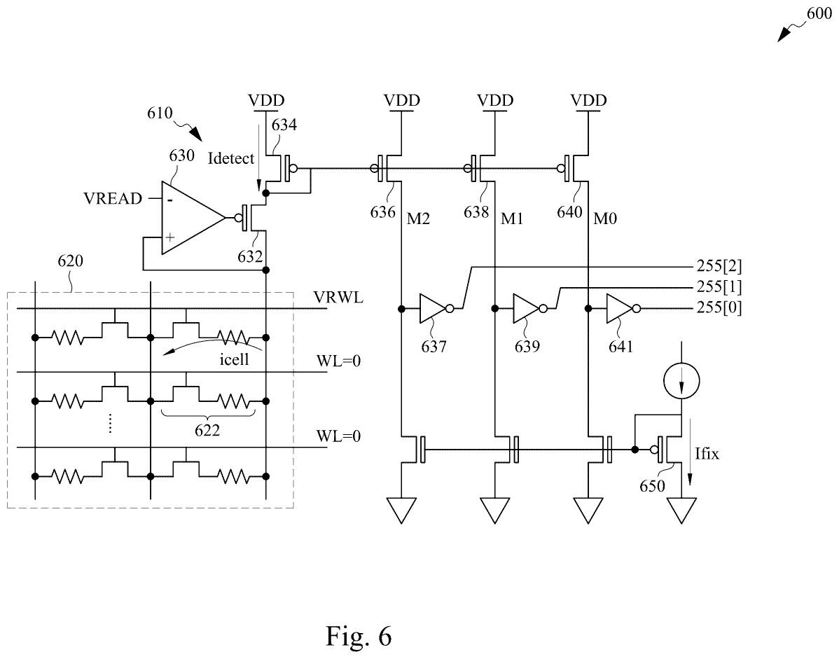

FIG. 6 illustrates a schematic diagram 600 including a current detector 610 coupled to a memory array 620 and configured to provide control signals for the switches included in the voltage control circuit 200 (FIG. 2), in accordance with various embodiments of the present disclosure. As shown, the memory array 620 may include a plural number of memory cells 622 arranged over a number of BLs and a number of WLs; and the current detector 610 can include an error amplifier 630, a standby current source 632, and a number of current mirrors. For example, a first current mirror can be operatively formed by transistor 634 and transistor 636 (or M2); a second current mirror can be operatively formed by transistor 634 and transistor 638 (or M1); and a third current mirror can be operatively formed by transistor 634 and transistor 640 (or M0). In some embodiments, the transistor 634 is configured to conduct a current (I_{detect}) that flows through one or more of the activated memory cells 622.

Further, the transistors 636 to 640 may have respectively different W/L ratios. As such, the currents mirrored by the transistors 636 to 640 are different. The different currents can then be compared with a fixed current (I_{fix}) provided by transistor 650, so as to generate different combination of control signals for activating/deactivating the switches of the voltage control circuit 200, e.g., 255[0], 255[1], 255[2], etc. In general, when a current level of I_{detect} tends to be low (e.g., lower than I_{fix}), the current detector 610 can cause a greater number of switches of the voltage control circuit 200 to be activated, so as to allow the voltage control circuit 200 to provide a higher level of current. Conversely, when the current level of I_{detect} tends to be high (e.g., higher than I_{fix}), the current detector 610 can cause a fewer number of switches of the voltage control circuit 200 to be activated.

For example, the W/L ratio of the transistor 636 to the W/L ratio of the transistor 634 may be equal to 2; the W/L ratio of the transistor 638 to the W/L ratio of the transistor 634 may be equal to 1; and the W/L ratio of the transistor 640 to the W/L ratio of the transistor 634 may be equal to 0.5. The transistors 636, 638, and 640 can thus mirror 2×I_{detect}, 1×I_{detect}, and 0.5×I_{detect}, respectively. When I_{detect} is detected to be 20 μA, the transistor 636 (M2) can conduct a current of about 40 μA, the transistor 638 (M1) can conduct a current of about 20 μA, and transistor 640 (M0) can conduct a current of about 10 μA. Assuming I_{fix} is provided at 8 μA, each of the currents flowing through the transistors 636 to 640 is higher than I_{fix}, and thus, the control signals for the switches 255[2], 255[1], 255[0] are provided (through inverters 637, 639, and 641) as logic 0, logic 0, and logic 0, respectively. In various embodiments, when the control signal is provided at logic 0, the corresponding switch 255 may be deactivated; and when the control signal is provided at logic 1, the corresponding switch 255 may be activated.

Continuing with the same example where the transistors 636, 638, and 640 mirror 2×I_{detect}, 1×I_{detect}, and 0.5×I_{detect}, respectively, when I_{detect} is detected to be 10 μA (with I_{fix} still provided at 8 μA), the currents flowing through the transistors 636 to 640 are equal to 20 μA, 10 μA, and 5 μA, respectively. Only the current flowing through the transistor 640 is lower than Ifix. Accordingly, the control signals for the switches 255[2], 255[1], 255[0] are provided (through inverters 637, 639, and 641) as logic 0, logic 0, and logic 1, respectively. When I_{detect} is detected to be 5 μA (with I_{fix} still provided at 8 μA), the currents flowing through the transistors 636 to 640 are equal to 10 μA, 5 μA, and 2.5 μA, respectively. Only the current flowing through the transistor 636 is higher than I_{fix}. Accordingly, the control signals for the switches 255[2], 255[1], 255[0] are provided (through inverters 637, 639, and 641) as logic 0, logic 1, and logic 1, respectively. When I_{detect} is detected to be 1 μA (with I_{fix} still provided at 8 μA), the currents flowing through the transistors 636 to 640 are equal to 2 μA, 1 μA, and 0.5 μA, respectively. All the currents flowing through the transistors 636 to 640 are lower than I_{fix}. Accordingly, the control signals for the switches 255[2], 255[1], 255[0] are provided (through inverters 637, 639, and 641) as logic 1, logic 1, and logic 1, respectively.

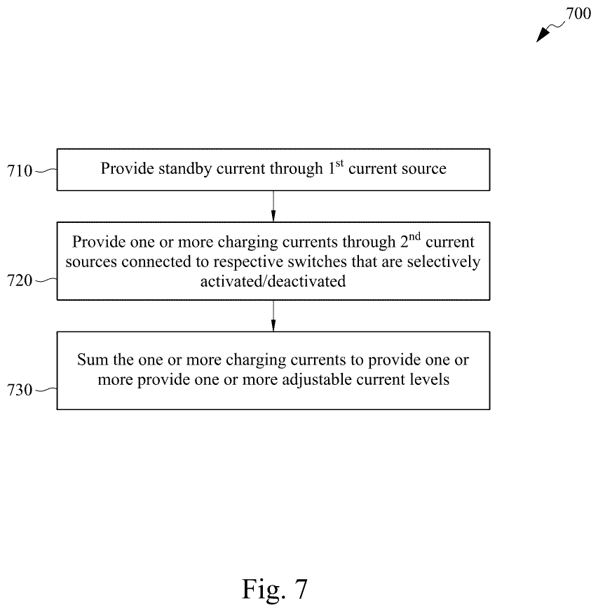

FIG. 7 illustrates a flow chart of an example method 700 for operating a voltage control circuit to generate one or more adjustable current levels (and corresponding voltage levels), in accordance with various embodiments of the present disclosure. The operations of the method 700 may be performed by the components described above in, e.g., FIG. 2, and thus, some of the reference numerals used above may be re-used the following discussion of the method 700. Further, it is understood that the method 700 has been simplified, and thus, additional operations may be provided before, during, and after the method 700 of FIG. 7, and that some other operations may only be briefly described herein.

The method 700 starts with operation 710 of providing a standby current through a first current source that is controlled based on an error voltage. Using the voltage control circuit 200 (FIG. 2) as a representative example, the transistor (or a standby current source) 220, controlled by the error voltage outputted by the error amplifier 210, can provide a standby current. In some embodiments, at least the error amplifier 210 and the transistor 220 can operatively serve as a global LDO regulator configured to provide a regulated output voltage (Vₓ).

The method 700 proceeds to operation 720 of providing one or more charging currents through one or more respective second current sources that are also controlled by the error voltage. In various embodiments, the one or more charging currents are provided by the one or more second current sources that are selectively connected to one or more switches, respectively. With the example above, the transistors 250[0] to 250[N−1], which operatively serve as the second current sources, respectively, can be controlled by the same error voltage provided by the error amplifier 210. The transistors 250[0] to 250[N−1] can be coupled to switches 255[0] to 255[N−1], respectively, so as to selectively conduct respective charging currents. When one of the switches is activated, the corresponding transistor (or the corresponding second current source) can provide a charging current to the coupled current mirror 260 through the node 259.

The method 700 proceeds to operation 730 of summing the one or more charging currents to provide one or more adjustable current levels for operating a memory array. In general, a greater number of the switches 255 being activated results in a greater number of charging currents provided to the current mirror 260, and vice versa. In various embodiments, the current mirror 260 can sum all the charging current(s) being provided through the respective second current sources, and provide an output current for operating a memory array. For example, the output current can be provided for a local LDO regulator to generate an operation voltage for the memory array. With the different number of charging currents contributing to the output current, the voltage control circuit 200 can provide a plurality of adjustable current levels for operating the memory array.

In one aspect of the present disclosure, a voltage control circuit is disclosed. The voltage control circuit includes an amplifier having a first terminal and a second terminal; a first current source having a control terminal connected to an output terminal of the amplifier and configured to provide a first current; a plurality of second current sources each having a control terminal connected to the output terminal of the amplifier and each configured to provide a second current; and a plurality of switches, each of the plurality of switches having a first terminal selectively connected to a first terminal of a corresponding one of the second current sources. One or more of the plurality of switches are configured to be activated to conduct one or more of the corresponding second currents, causing the circuit to provide a plurality of adjustable voltages.

In another aspect of the present disclosure, a voltage control circuit is disclosed. The voltage control circuit includes an amplifier configured to provide an error voltage determined based on a difference between a reference voltage and a divided voltage; a first current source including a first transistor, wherein the first transistor is gated by the error voltage and configured to provide a first current; a plurality of second current sources each including a second transistor, wherein the second transistors are also gated by the error voltage and are each configured to provide a respective second current; a plurality of switches, wherein each of the plurality of switches has a first terminal selectively connected to a corresponding one of the second current sources; and a current mirror permanently connected to second terminal of each of the plurality of switches. At least one of the plurality of switches is configured to be activated to conduct the corresponding second current for the current mirror to mirror.

In yet another aspect of the present disclosure, a method for operating a voltage control circuit is disclosed. The method includes providing a standby current through a first current source that is controlled based on an error voltage. The method includes providing one or more charging currents through one or more respective second current sources that are also controlled by the error voltage. The one or more charging currents are provided by the one or more second current sources based on activation/deactivation of one or more switches connected to the one or more second current sources, respectively. The method includes summing the one or more charging currents to provide one or more adjustable current levels for operating a memory array.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit, comprising:
an amplifier having a first terminal and a second terminal;
a first current source having a control terminal connected to an output terminal of the amplifier and configured to provide a first current;
a plurality of second current sources each having a control terminal connected to the output terminal of the amplifier and each configured to provide a second current; and
a plurality of switches, each of the plurality of switches having a first terminal selectively connected to a first terminal of a corresponding one of the second current sources;
wherein one or more of the plurality of switches are configured to be activated to conduct one or more of the corresponding second currents, causing the circuit to provide a plurality of adjustable voltages.

2. The circuit of claim 1, further comprising a current mirror permanently connected to a second terminal of each of the plurality of switches.

3. The circuit of claim 2, wherein the current mirror is configured to provide the plurality of adjustable voltages based on the one or more second currents.

4. The circuit of claim 1, wherein a first one of the plurality of adjustable voltages is configured to control a first transistor with a first conductive type, and a second one of the plurality of adjustable voltages is configured to control a second transistor with a second conductive type.

5. The circuit of claim 4, wherein the first transistor is configured to provide a current for a first voltage control circuit operatively coupled to a memory array, and the second transistor is configured to provide a current for a second voltage control circuit operatively coupled to the memory array.

6. The circuit of claim 5, wherein the memory array includes a plurality of non-volatile memory bit cells.

7. The circuit of claim 6, wherein a number of the switches that are activated is inversely proportional to a detected current flowing through one or more of the non-volatile memory bit cells.

8. The circuit of claim 1, wherein the first current source has a first terminal connected to a supply voltage and a second terminal coupled to the second terminal of the amplifier through at least a voltage divider and a mirror compensation circuit, and wherein the first terminal of the amplifier is configured to receive a reference voltage.

9. The circuit of claim 8, wherein the second current sources each have a first terminal connected to the supply voltage and a second terminal selectively connected to the first terminal of the corresponding switch.

10. The circuit of claim 9, wherein none of the second terminals of the second current sources is connected to the first current source.

11. A circuit, comprising:
an amplifier configured to provide an error voltage determined based on a difference between a reference voltage and a divided voltage;
a first current source including a first transistor, wherein the first transistor is gated by the error voltage and configured to provide a first current;
a plurality of second current sources each including a second transistor, wherein the second transistors are also gated by the error voltage and are each configured to provide a respective second current;
a plurality of switches, wherein each of the plurality of switches has a first terminal selectively connected to a corresponding one of the second current sources; and
a current mirror permanently connected to second terminal of each of the plurality of switches;
wherein at least one of the plurality of switches is configured to be activated to conduct the corresponding second current for the current mirror to mirror.

12. The circuit of claim 11, wherein the first transistor and the second transistor are each a p-type transistor.

13. The circuit of claim 11, wherein the current mirror is configured to provide a plurality of adjustable voltages based on a number of the switches being activated.

14. The circuit of claim 13, wherein the plurality of adjustable voltages are provided to respective voltage control circuits operatively coupled to a memory array.

15. The circuit of claim 14, wherein the memory array includes a plurality of non-volatile memory bit cells.

16. The circuit of claim 11, wherein the amplifier has a first terminal configured to receive the reference voltage and a second terminal configured to receive the divided voltage.

17. The circuit of claim 16, wherein the first transistor has a first source/drain terminal connected to a supply voltage and a second source/drain terminal coupled to an output terminal of the amplifier through a mirror compensation circuit, and the amplifier is configured to provide the error voltage at its output terminal, and wherein the second source/drain terminal of the first transistor is coupled to the second terminal of the amplifier through a voltage divider.

18. The circuit of claim 17, wherein the second transistor of each of the second current sources has a first source/drain terminal connected to the supply voltage and a second source/drain terminal selectively connected to the first terminal of the corresponding switch.

19. A method, comprising:
providing a standby current through a first current source that is controlled based on an error voltage;
providing one or more charging currents through one or more respective second current sources that are also controlled by the error voltage, wherein the one or more charging currents are provided by the one or more second current sources based on activation/deactivation of one or more switches connected to the one or more second current sources, respectively; and
summing the one or more charging currents to provide one or more adjustable current levels for operating a memory array.

20. The method of claim 19, wherein the memory array includes a plurality of non-volatile memory bit cells.
